(19) United States
(12) Patent Application Publication
(10) Pub. No.: US 2018/0230597 A1
(43) Pub. Date: Aug. 16, 2018

(54) METHOD AND APPARATUS OF REMOTE PLASMAS FLOWABLE CVD CHAMBER

(71) Applicant: Applied Materials, Inc., Santa Clara, CA (US)

(72) Inventors: Ying MA, Castro Valley, CA (US); Daemian RAJ, Fremont, CA (US); Martin Jay SEAMONS, San Jose, CA (US); Ankit POKHREL, Palo Alto, CA (US); Greg CHICHKANOFF, Mountain View, CA (US); Yizhen ZHANG, San Jose, CA (US); Jingmei LIANG, San Jose, CA (US); Jay D. PINSON, II, San Jose, CA (US); Dongqing LI, Fremont, CA (US); Juan Carlos ROCHA-ALVAREZ, San Carlos, CA (US)

(21) Appl. No.: 15/432,619

(22) Filed: Feb. 14, 2017

(51) Int. Cl. C23C 16/505; C23C 16/455; C23C 16/458

(52) U.S. Cl. CPC C23C 16/505; C23C 16/458; C23C 16/45565

(57) ABSTRACT

Embodiments disclosed herein generally relate to a plasma processing system. The plasma processing system includes a processing chamber, a chamber seasoning system, and a remote plasma cleaning system. The processing chamber has a chamber body defining a processing region and a plasma field. The chamber seasoning system is coupled to the processing chamber. The chamber seasoning system is configured to season the processing region and the plasma field. The remote plasma cleaning system is in communication with the processing chamber. The remote plasma cleaning system is configured to clean the processing region and the plasma field.

### BACKGROUND

### Field

Implementations described herein generally relate to a substrate processing apparatus, and more specifically to an improved plasma enhanced chemical vapor deposition chamber.

### Description of the Related Art

Semiconductor processing involves a number of different chemical and physical processes enabling minute integrated circuits to be created on a substrate. Layers of materials, which make up the integrated circuit, are created by chemical vapor deposition, physical vapor deposition, epitaxial growth, and the like. Some of the layers of material are patterned using photoresist masks and wet or dry etching techniques. The substrate utilized to form integrated circuits may be silicon, gallium arsenide, indium phosphide, glass, or other appropriate material.

In the manufacture of integrated circuits, plasma processes are often used for deposition or etching of various material layers. Plasma processing offers many advantages over thermal processing. For example, plasma enhanced chemical vapor deposition (PECVD) allows deposition processes to be performed at lower temperatures and at higher deposition rates than achievable in analogous thermal processes. Thus, PECVD is advantageous for integrated circuit fabrication with stringent thermal budgets, such as for very large scale or ultra-large scale integrated circuit (VLSI or ULSI) device fabrication.

Conventional PECVD configurations use remote plasma system (RPS) generators to generate radicals from outside the chamber. The radicals formed in the RPS generator are plasmas are then delivered and distributed above the substrate. However, because of the long delivery path from the RPS generator to the area above the substrate, there is a high recombination rate, which leads to chamber to chamber variation.

Accordingly, there is a need for an improved PECVD chamber.

### SUMMARY

Implementations disclosed herein generally relate to a plasma processing system. The plasma processing system includes a processing chamber, a chamber seasoning system, and a remote plasma cleaning system. The processing chamber has a chamber body defining a processing region and a plasma field. The chamber seasoning system is coupled to the processing chamber. The chamber seasoning system is configured to season the processing region and the plasma field. The remote plasma cleaning system is in communication with the processing chamber. The remote plasma cleaning system is configured to clean the processing region and the plasma field.

In another implementation, a method of seasoning a processing chamber is disclosed herein. A first region of the processing chamber is seasoned. A plasma is generated in the processing chamber. A second region of the processing chamber is seasoned.

In another implementation, a method of cleaning a processing system is disclosed herein. A plasma is generated in a remote plasma system. The plasma is directed to an upper split manifold of the remote plasma system. A first region of the processing chamber is cleaned. A second region of the processing chamber is cleaned subsequent to cleaning the first region of the processing chamber. The plasma is directed rom the upper split manifold to a lower split manifold of the remote plasma system.

### BRIEF DESCRIPTION OF THE DRAWINGS

So that the manner in which the above recited features of the present disclosure can be understood in detail, a more particular description of the disclosure, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective embodiments.

FIG. 1 is a schematic cross sectional view of a plasma system, according to one implementation.

FIG. 2 is a partial top view of a selective modulation device of the plasma system of FIG. 1, according to one implementation.

FIG. 3 is a partial bottom view of a showerhead of the plasma system of FIG. 1, according to one implementation.

FIG. 4 is a simplified view of the processing system of FIG. 1, having a chamber seasoning system, according to one implementation.

FIG. 5 is a flow diagram illustrating a method of seasoning a processing chamber, such as plasma system in FIG. 1.

FIG. 6 is a simplified view of the processing system of FIG. 1, having a remote plasma system, according to one implementation.

FIG. 7 is a flow diagram illustrating a method of cleaning a processing chamber, such as processing system in FIG. 1.

For clarity, identical reference numerals have been used, where applicable, to designate identical elements that are common between figures. Additionally, elements of one embodiment may be advantageously adapted for utilization in other implementations described herein.

### DETAILED DESCRIPTION

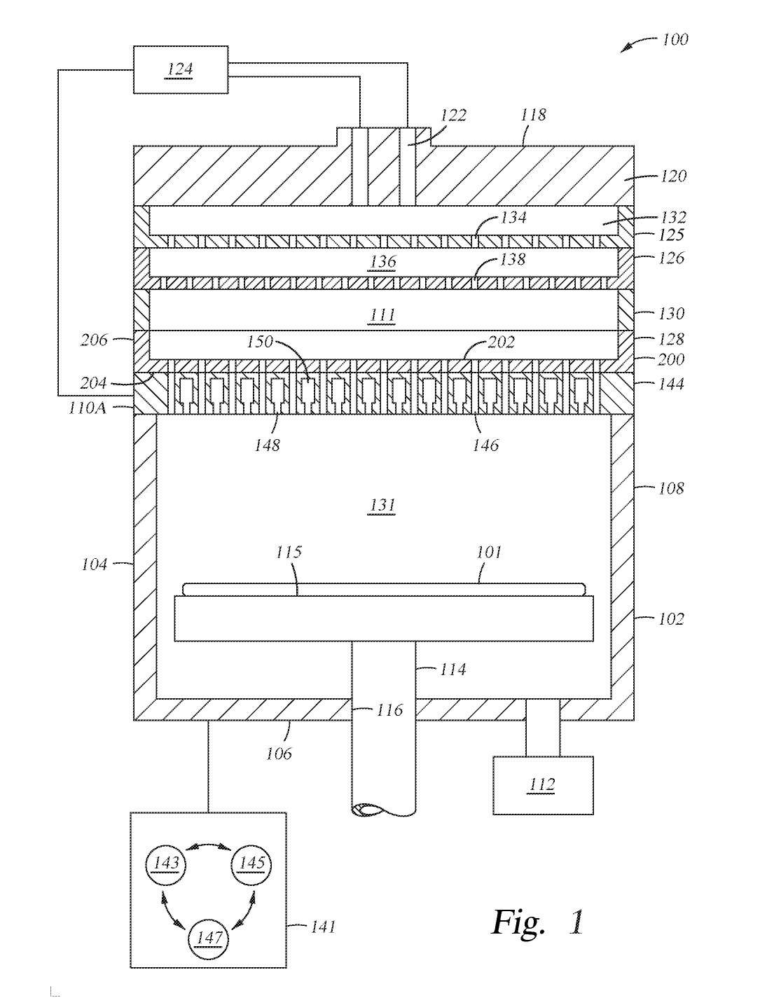

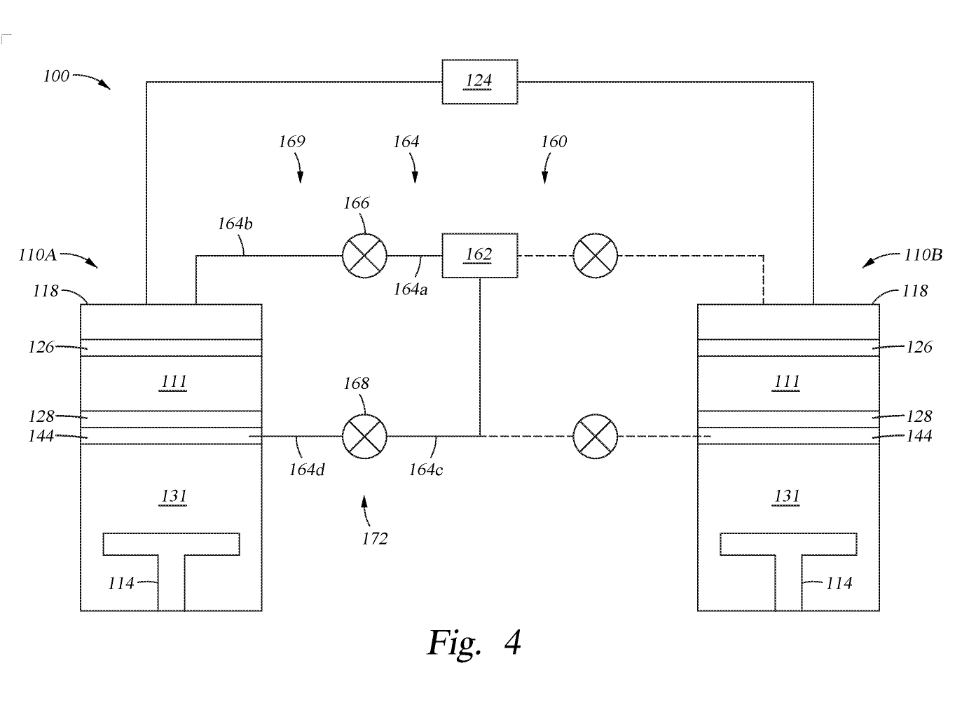

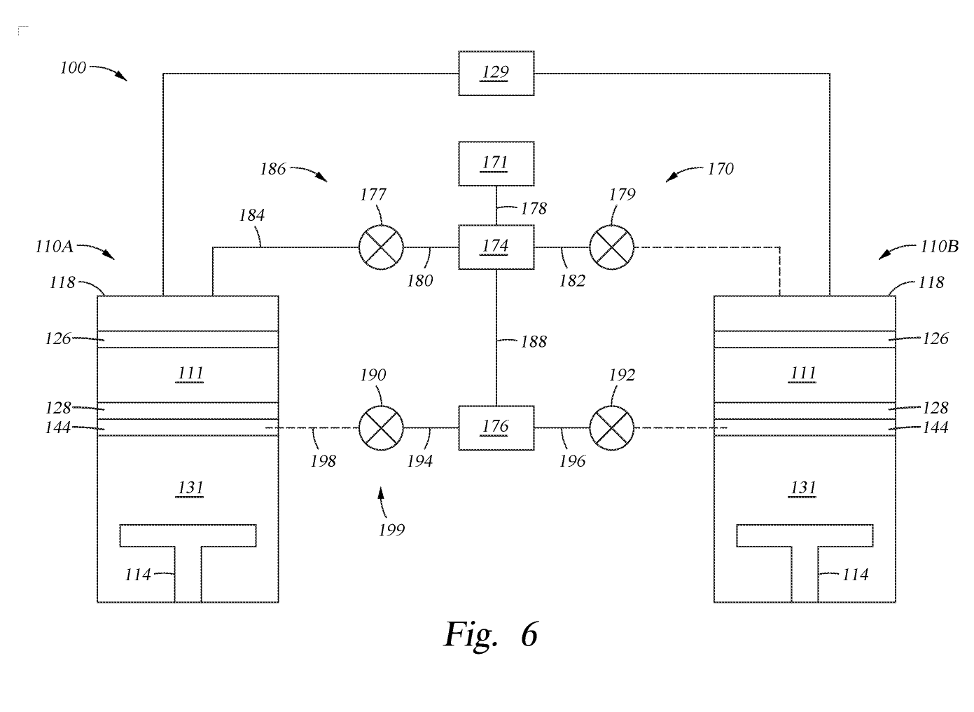

FIG. 1 is a schematic cross sectional view of a processing system 100. The plasma system 100 generally comprises a chamber body 102 having sidewalls 104, a bottom wall 106, and a shared interior sidewall 108. The shared interior side wall 108, the sidewalls 104, and the bottom wall 106 define a pair of processing chambers 110A and 1106. The details of chamber 110A are described herein in detail. Process chamber 1106 is depicted in FIGS. 4 and 6. Process chamber 1106 is substantially similar to process chamber 110A, and the description thereof has been omitted for clarity. A vacuum pump 112 is coupled to the processing chambers 110A, 110B.

The processing chamber 110A may include a pedestal 114 disposed therein. The pedestal 114 may extend through a respective passage 116 formed in the bottom wall 106 of the processing system 100. The pedestal 114 includes a substrate receiving surface 115. The substrate receiving surface 115 is configured to support a substrate 101 during processing. Each pedestal 114 may include substrate lift pins (not shown) disposed through the body of the pedestal 114. The substrate lift pins selectively space the substrate 101 from the pedestal 114 to facilitate exchange of the substrate 101 with a robot (not shown) utilized for transferring the substrate into and out of the processing chamber 110A.

The processing chamber 110A further includes an upper manifold 118. The upper manifold 118 may be coupled to a top portion of the chamber body 102. The upper manifold 118 includes a gas box 120 having one or more gas passages 122 formed therein. The gas box 120 is coupled to one or more gas sources 124. The one or more gas sources 124 may provide one or more process gases to the processing chamber 110A during processing.

The processing system 100 further includes a faceplate 126, a ion blocker plate 128, and a spacer 130 separating the faceplate 126 from the ion blocker plate 128. In some implementations, the processing system 100 may further include a blocker plate 125 positioned between the faceplate 126 and the gas box 120. The blocker plate 125 positioned beneath the gas box 120 forms a first plenum 132 therebetween. The first plenum 132 is configured to receive the one or more process gases from the one or more gas passages 122. The gas may flow from the first plenum 132 through the blocker plate 125 via one or more openings 134 formed therein. The one or more openings 134 are configured to allow for passage of gas from a top side of the blocker plate 125 to a bottom side of the blocker plate 125.

The faceplate 126 is positioned beneath the blocker plate 125, defining second plenum 136 therebetween. The one or more openings 134 of the blocker plate 125 are in fluid communication with the second plenum 136. The process gas is flowed through the blocker plate 125 via the one or more openings 134 and into the second plenum 136. From the second plenum 136, the process gas may pass through the faceplate 126 via one or more openings 138 formed therein.

The ion blocker plate 128 is positioned beneath the faceplate 126. The spacer 130 separates the ion blocker plate 128 from the faceplate 126, forming a plasma field 111. The spacer 130 may be an insulating ring that allows an alternating current (AC) potential to be applied to the faceplate 126 relative to the ion blocker plate 128. The spacer 130 may be positioned between the faceplate 126 and the ion blocker plate 128 to enable a capacitively coupled plasma (CCP) to be formed in the plasma field 111. A third plenum 140 is defined between the faceplate 126 and the ion blocker plate 128. The third plenum 140 is configured to receive the gas from the second plenum 136 via the one or more openings 138.

The faceplate 126 and the ion blocker plate 128 work as two electrodes of RFs and the spacer 130 acts as the isolator. A plasma field 111 is formed in the cavity between the two electrodes (i.e., faceplate 126, ion blocker plate 128). The gas is dissociated in the plasma field 111. The one or more openings 138 formed in the faceplate 126 allows the gas to enter the plasma field 111.

The ion blocker plate 128 may include multiple apertures formed through the ion blocker plate 128. The multiple apertures are configured to suppress the migration of ionically charged species through the ion blocker plate 128, while allowing uncharged neutral or radical species to pass through the ion blocker plate 128 into a processing region 131.

The processing system 100 may further include a showerhead 144 positioned beneath the ion blocker plate 128. The showerhead 144 defines the upper boundary of the processing region 131 between the pedestal 114 and the showerhead 144. In the embodiment depicted in FIG. 1, the showerhead 144 may be a dual channel shower head. The showerhead 144 includes a first plurality of openings 146, a second plurality of openings 148, and one or more gas passages 150 formed therein. The first plurality of openings 146 is in fluid communication with the one or more apertures formed in the ion blocker plate 128. The first plurality of openings 146 allow for radicals in the plasma formed in the plasma field 111 to travel through the showerhead 144 and into the substrate processing region 131. The one or more gas passages 150 are configured to receive a gas from the gas source 124. For example, the one or more gas passages 150 are configured to receive a precursor gas from gas source 124.

The second plurality of openings 148 is formed in the showerhead 144 such that the second plurality of openings 148 provides fluid communication between the one or more gas passages 150 and the processing region 131. As such, the radicals that exit the plasma field 111 and enter the processing region 131 via the first plurality of openings 146 may mix and react with the precursor gas provided by the one or more gas passages 150 via the second plurality of openings 148. This configuration differs from preexisting PECVD chambers in that the precursor and reaction gas do not enter the plasma field 111 together and react therein; rather, because the showerhead 144 is positioned below the ion blocker plate 128, the precursor exits the plasma field 111 first, and then enters into the showerhead 144. Thus, the mixing and reaction between the precursor and the radicals are outside of the plasma field 111. As such, the combination of indirect capactively coupled plasma and the later introduced precursor provides a better gap-fill and wider film flowability window.

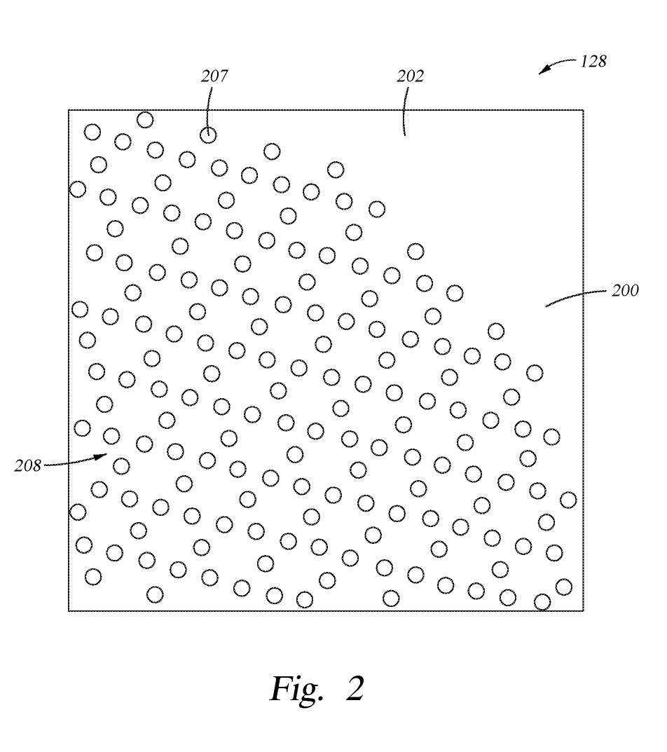

FIG. 2 illustrates a partial top view of the ion blocker plate 128, according to one embodiment. The ion blocker plate 128 includes a disc shaped body 200 having a top surface 202, a bottom surface 204, and an outer edge 206. The top surface 202 faces the faceplate 126 and the bottom surface 204 faces the showerhead 144. The ion blocker plate 128 includes one or more apertures 207 formed therein. The one or more apertures 207 allow for gas to pass from the top surface 202 of the ion blocker plate 128 to the bottom surface 204. In one implementation, the one or more apertures 207 are arranged in a pattern 208. For example, the apertures 207 may be arranged in a hex pattern.

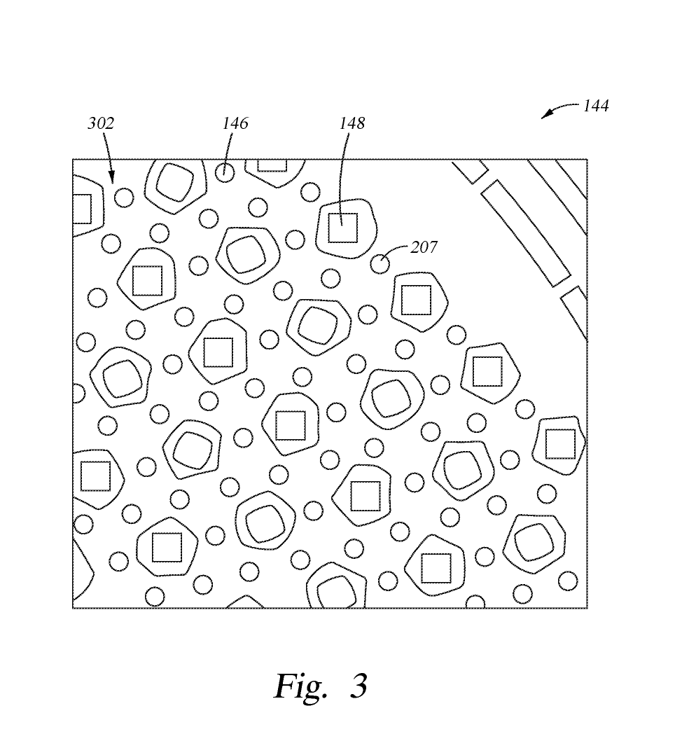

FIG. 3 illustrates a partial bottom view of the showerhead 144 according to one implementation. In FIG. 3, the showerhead 144 is positioned beneath the ion blocker plate 128 of FIGS. 1 and 2. As discussed in conjunction with FIG. 1, the showerhead 144 includes the first plurality of openings 146 and the second plurality of openings 148. The first and second pluralities of openings 146, 148 are arranged in a pattern 302. For example, the first and second pluralities of openings 146, 148 are arranged in a hex pattern. The first and second pluralities of openings 146, 148 are arranged such that the first and second pluralities of openings 146, 148 are offset from the one or more apertures 207 formed in the ion blocker plate 128. The offset arrangement aids in minimizing the direct plasma formation and minimizing the ion density, both of which could result in arcing or possible damage on substrate pre-layers. Additionally, the offset arrangement aids in retaining radicals and increasing film uniformity of the substrate 101.

During operation, process gas may be supplied to the plasma field 111. For example, the process gas may be an oxygen based gas. RF may be applied to the ion blocker plate 128 and the faceplate 126 such that a plasma is formed in the plasma field 111. Generally, the generated plasma may include three types of species: radicals (neutral), ions, and electrons. Radicals in the plasma field may travel from the plasma field 111 through the ion blocker 128. The ion blocker 128 is configured to filter or reduce the ions in the plasma, while allowing radicals to flow through the one or more apertures 207 formed therein. The radicals may flow through the openings 146 in the showerhead 144, and into the processing region 131. As such, the effect is to use a capacitively coupled plasma similar to that of remote plasma applications. In some implementations, a precursor may be introduced below the ion blocker 128 via the one or more gas passages 150 formed in the showerhead 144. For example, the precursor gas may be a silicon based gas. As such, the precursor may only mix with the radicals that separated from the plasma formed in the plasma field 111 when both the precursor and the radicals enter the processing region. Thus, the reaction between the precursor and the plasma radicals is primarily chemical, rather than physical and chemical.

The processing system 100 includes a chamber seasoning system 160. The chamber seasoning system 160 is configured to season areas of the chamber 110A to reduce potential contamination of the substrate 101 during processing. FIG. 4 illustrates the chamber seasoning system 160 with a simplified view of the processing system 100 for clarity. The chamber seasoning system 160 includes a gas source 162, one or more feed lines 164 coupling the gas source to the chamber 110A, a first valve 166, and a second valve 168. A first feed line 164a couples the gas source 162 to the first valve 166. The first valve 166 is coupled to the upper manifold 118 via a second feed line 164b. The first and second feed lines 164a, 164b provide a first gas flow path 169 from the gas source 162 to the upper manifold 118. The first valve 166 is configurable between an open state and a closed state, thus allowing or blocking the passage of gas therethrough from the gas source 162 to the upper manifold 118.

A third feed line 164c couples the gas source 162 to the second valve 168. The second valve 168 is coupled to the showerhead 144 via a fourth feed line 164d. The third and fourth feed lines 164c, 164d provide a second gas flow path 172 from the gas source 162 to the showerhead 144. The second valve 168 is configurable between an open state and a closed state, thus allowing or preventing the passage of gas therethrough, from the gas source 162 to the showerhead 144.

The first gas flow path 169 is used for a seasoning process in the plasma field 111 of the chamber. For example, when it is desired to season the plasma field 111, the first valve 166 is switched to an open state and the second valve 168 is switched to a closed state. The first valve 166 in the open state allows for entry of a precursor with carrier gas to enter into the upper manifold 118. The gas may enter the first manifold between the blocker plate 125 and the gas box 120 via the one or more gas passages 122. The precursor may then mix and react with the reaction gas and the carrier gas. The mixture may then flow from the first manifold, through the blocker plate 125, into the second manifold, through the faceplate 126, and into the plasma field 111. The top seasoning process is used to season the chamber 110A wall in the plasma field 111 to avoid direct ion bombardment on chamber 110A component surfaces, which may result in high trace metal and particles.

The second gas flow path 172 is used for a seasoning process in the processing region 131 of the chamber 110A. For example, when it is desired to season the processing region 131, the second valve 168 is positioned in the open state and the first valve 166 is positioned in the closed state. The second valve 168 in the open state allows for entry of a precursor with carrier gas to enter processing region 131 via the showerhead 144. The precursor gas, along with the carrier gas, enters the chamber 110A through the showerhead 144. The mixture of the precursor and carrier gases fills the one of more gas passages 150 formed in the showerhead 144. The reaction gas enters the chamber 110A through the one or more gas passages 122 of the upper manifold 118. The reaction gas is dissociated in the plasma field 111, defined above the showerhead 144. After the dissociation, the mixture of gas and radicals from the plasma passes through the first plurality of openings of the showerhead 144 while the mixture of precursor and carrier gases passes through the second plurality of openings of the showerhead 144. The mixture of precursor and carrier gases mixes with the mixture of gas and radicals in the processing region 131 below the showerhead 144. The bottom seasoning process is used for deposition on chamber sidewalls 104 beneath the showerhead 144, while the main processing occurs.

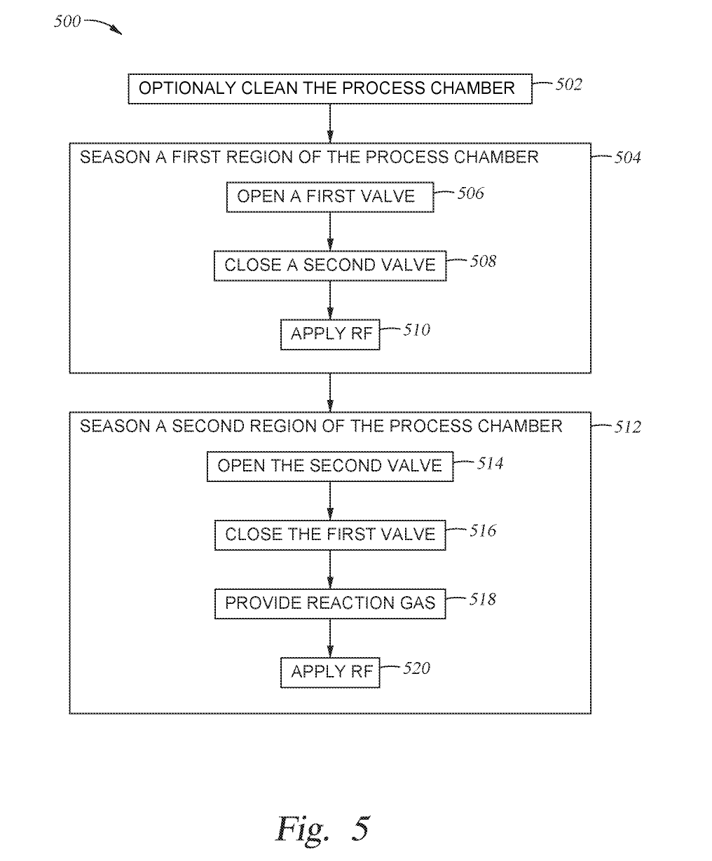

FIG. 5 is a flow diagram illustrating a method of seasoning a processing chamber, such as processing system 100 in FIG. 1. The seasoning process is typically used to deposit a film onto internal surfaces of the chamber 110A following a cleaning process. The deposited film reduces the contamination level during processing by preventing residual particles adhered to the surfaces of the chamber 110A from being dislodged and falling onto a substrate being processed. The method may begin at block 502. At block 502, an optional cleaning sequence may be performed in the process chamber 110A. For example, following a deposition process in the process chamber 110A, such as a SiO or a SiOC gap fill process, the process chamber 110A may undergo a cleaning process to remove residual material from internal chamber surfaces. An example cleaning process discussed for processing system 100 is discussed in more detail below in conjunction with FIG. 5.

At block 504, a first region of the processing chamber 110A undergoes a seasoning process. For example, the first region of the processing chamber 110A may be the plasma field 111 between the ion blocker plate 128 and the showerhead 144. Block 504 includes sub-block 506-510. At sub-block 506, a first valve 166 in the chamber seasoning system 160 is opened. The first valve 166 in the chamber seasoning system 160 provides fluid communication from the one or more gas sources to the plasma field 111. In the open position, the seasoning gases may flow from the gas sources to the plasma field 111. For example, the seasoning gases may comprises a mixture of precursor cases with carrier gases that mix with reaction gases and carrier gases provided by gas source 124. At sub-block 508, a second valve 168 in the chamber seasoning system 160 is either maintained in the closed position or configured to the closed position. The second valve 168 in the chamber seasoning system 160 provides fluid communication from the one or more gas sources to the processing region 131 defined between the showerhead 144 and the pedestal 114 via the showerhead 144. At sub-block 510, RF power is applied to the showerhead 144 and the ion blocker plate 128 to strike a plasma within the plasma field 111. For example, when the seasoning gases enter the plasma field 111 through the ion blocker plate 128, RF is applied to the showerhead 144 and the ion blocker plate 128. As such, the reaction gas begins to dissociate, and the deposition of a film begins almost immediately because of the addition of the precursor. Thus, both dissociation and deposition begin almost simultaneously when RF is applied.

At block 512, the second region of the processing chamber 110A undergoes a seasoning process. For example, the second region of the processing chamber 110A may be the processing region 131 between the showerhead 144 and the pedestal 114. Block 512 includes sub-block 514-520. At sub-block 514, the second valve 168 in the chamber seasoning system 160 is opened. The second valve 168 in the chamber seasoning system 160 provides fluid communication from the one or more gas sources to the processing region 131. In the open position, the seasoning gases may flow from the gas sources to the processing region 131. For example, the seasoning gases may comprises a mixture of precursor cases with carrier gases that6mix with reaction gases and carrier gases provided by gas source 124. At sub-block 516, the first valve 166 in the chamber seasoning system 160 is configured to the closed position. Closing the first valve 166 shuts off gas flow from the gas source to the plasma field 111 and forces the gas flow to travel down to the second valve. At sub-block 518, a reaction gas is provided to the processing chamber 110A. As such, the reaction gas enters the plasma field 111. At sub-block 520, RF power is applied to the showerhead 144 and the ion blocker plate 128 to strike a plasma within the plasma field 111. For example, when the reaction gas enters the plasma field 111, RF is applied to the showerhead 144 and the ion blocker plate 128. As such, the reaction gas begins to dissociate therein. Unlike the top seasoning, deposition does not occur within the plasma field 111 because the precursor gas has been provided to the showerhead 144 below plasma field 111, while no precursor gases flow through the plasma field 111. The precursor with carrier gas then enters into the showerhead 144. As such, the precursor with carrier gas exits the showerhead 144 through a first plurality of openings, and the plasma formed in the plasma field 111 exits the showerhead 144 through a second plurality of openings. Therefore, the precursor and carrier gas does not mix with the reaction gas until they enter the processing region 131. Thus, the mixture of gas and radicals passing through the showerhead 144 mixes and reacts with the precursor and carrier gases passing through the showerhead 144 in the processing region 131, such that deposition may occur.

In some embodiments, automatic frequency tuning (AFT) and pulsing (i.e., changing the duty cycle) of the RF frequency can aid in significantly adjusting the film properties, such as, deposition rate, RI, and flowability. For example, adjusting the RF frequency to 50 Hz at a 100% duty cycle for 60 seconds may yield a deposition thickness of about 983 Å and a refractive index of about 1.4 for flowability. In another example, adjusting the RF frequency to 50 Hz at a 100% duty cycle for about 60 seconds may yield a thickness of about 159 Å and a refractive index of about 1.5 for film roughness.

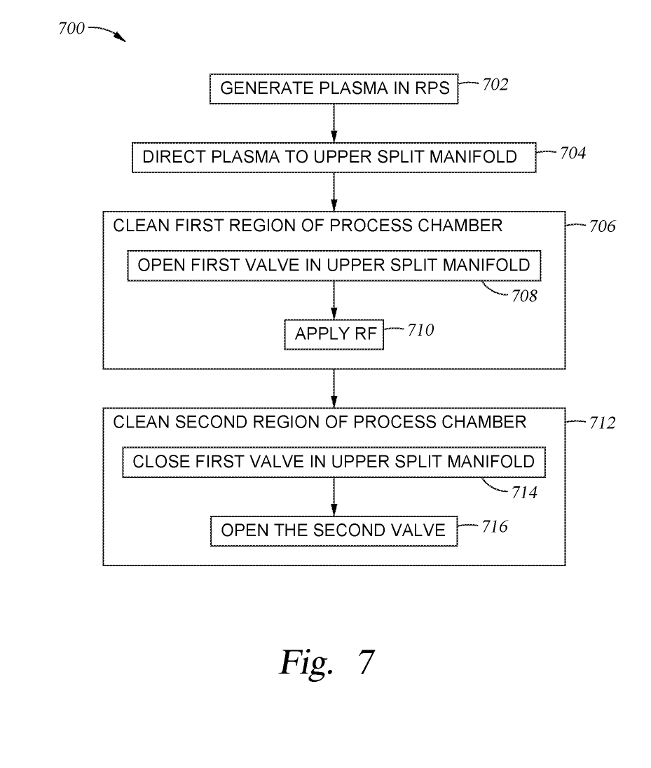

The processing system 100 further includes an RPS clean system 170. The RPS clean system 170 is illustrated in FIG. 7 with a simplified view of the plasma processing system 100 for clarity. The RPS clean system 170 includes a remote plasma generator 171, an upper split manifold 174, and a lower split manifold 176. The remote plasma generator 171 is coupled to the upper split manifold 174. The remote plasma generator 171 is configured to generate a plasma therein for a chamber clean process. For example, the remote plasma generator 171 is configured to generate a plasma comprising fluorine radicals, which is created by splitting fluorine using the energy from the plasma. The remote plasma generator 171 may be coupled to the upper split manifold 174 via a conduit 178. The upper split manifold 174 is coupled to a first valve 177 and a second valve 179. Each valve 177, 179 is switchable between an open state and a closed state. The upper split manifold 174 is coupled to the first valve 177 via a first conduit 180. The upper split manifold 174 is coupled to the second valve via a second conduit 182. A third conduit 184 couples the first valve 177 to the upper manifold 118. The first conduit 180 and the third conduit 184 collectively form a first cleaning flow path 186 from the upper split manifold 174 to the upper manifold 118. When the first valve 177 is switched to the open state, the radicals from the plasma flows from the remote plasma generator 171 into the upper split manifold 174 and into the upper manifold 118. If a cleaning process to a top of the chamber is not desired, the first valve 177 is in the closed position.

The upper split manifold 174 is coupled to the lower split manifold 176 via a conduit 188. When the valves 177, 179 are in the closed position, the radicals from the remote plasma generator 171 are forced into the lower split manifold 176 via the conduit 188. The lower split manifold 176 is coupled to a first lower valve 190 and a second lower valve 192. Each lower valve 190, 192 is configurable between an open state and a closed state. The lower split manifold 176 is coupled to the first lower valve 190 via a first lower conduit 194. The lower split manifold 176 is coupled to the second lower valve 192 via a second lower conduit 196. A third lower conduit 198 couples the first lower valve 190 to the processing region 131. The first lower conduit 194 and the third lower conduit 198 collectively form a first lower cleaning flow path 199 from the lower split manifold 176 to the processing region 131. When the first lower valve 190 is in the open state and the upper valves 177, 179 are in the closed state, the radicals flow from the remote plasma generator 171 down into the lower split manifold 176 and into the processing region 131. If a cleaning process to the processing region 131 of the chamber is not desired, the first lower valve 190 is in the closed position.

The cleaning process is used because of the high non-uniform deposition thickness on component surfaces across the chamber. Because the precursor is introduced below the showerhead 144 during the deposition/bottom seasoning, only a very small portion of the precursor diffuses back above the showerhead 144. Therefore, the deposition thickness on the sidewall beneath the showerhead 144 is much higher than the sidewall above the showerhead 144. Because the cleaning process has to compensate the thickest film, using a top clean significantly overcleans the components above the showerhead 144, further causing the surface fluoridation and generate fluorine based particles. Thus, the bottom clean, in addition to the top clean, is desired.

FIG. 7 is a flow diagram illustrating a method of cleaning a processing chamber 110A in a processing system 100, such as processing chamber 110A in FIG. 1. The cleaning process may be performed following a deposition process in the process chamber 110A, such as a SiO or a SiOC gap fill process, the process chamber 110A may undergo a cleaning process to remove residual material from internal chamber components.

The method 700 begins at block 702. At block 702, a plasma is generated by a remote plasma source in the clean system 170. The plasma is generated in the remote plasma source by supplying a gas to the remote plasma source and applying an RF thereto. In one example, the plasma generated therein contains fluorine radicals. At block 704, the fluorine radicals are directed to the upper split manifold 174.

At block 706, a first region of the process chamber 110A undergoes a cleaning processing. For example, the first region of the process chamber 110A may be the plasma field 111 defined between the faceplate 126 and the ion blocker plate 128. Block 706 includes sub-blocks 708-710. At sub-block 708, a first valve 177 in the upper split manifold 174 is open. The first valve 177 in the upper split manifold 174 provides fluid communication between the upper split manifold 174 and the upper manifold 118 of the processing chamber 110A. As such, the radicals may flow from the upper split manifold 174 to the upper manifold 118 of the processing chamber 110A. At sub-block 710, RF is provided to the faceplate 126 and the ion blocker plate 128. The RF provided to the faceplate 126 and the ion blocker plate 128 helps prevent recombination of the fluorine radicals during the cleaning process.

At block 712, a second region of the process chamber 110A undergoes a cleaning processing. For example, the second region of the process chamber 110A may be the processing region 131 defined between the showerhead 144 and the pedestal 114. Block 712 includes sub-blocks 714-716. At sub-block 714, the first valve 177 in the upper split manifold 174 is closed. Closing the first valve 177 forces the radicals from the upper split manifold 174 to a bottom split manifold of the clean system 170. At sub-block 716, a second valve 190 in the bottom split manifold is configured to an open position. In the open position, the second valve 190 provides fluid communication between the lower split manifold 176 and the processing region 131. As such, the radicals may flow into the showerhead 144 and from the showerhead 144 into the processing region 131 to clean chamber 110A components within the processing region 131.

Optionally, at block 714, a purge gas is provided to the first region of the process chamber 110A as the second region of the process chamber 110A undergoes a cleaning process. For example, a purge gas may be provided to the plasma field 111 through the upper manifold 118 of the processing chamber 110A. The purge gas in the plasma field 111 aids in eliminating any back flow of plasma radicals from the processing region 131, through the showerhead 144 and the ion blocker plate 128. As such, the purge gas aids in maintaining the clean process only in the processing region 131.

Referring back to FIG. 1, the processing system 100 further includes a controller 141. The controller 141 includes programmable central processing unit (CPU) 143 that is operable with a memory 145 and a mass storage device, an input control unit, and a display unit (not shown), such as power supplies, clocks, cache, input/output (I/O) circuits, and the liner, coupled to the various components of the processing system to facilitate control of the substrate processing.

To facilitate control of the chamber 100 described above, the CPU 143 may be one of any form of general purpose computer processor that can be used in an industrial setting, such as a programmable logic controller (PLC), for controlling various chambers and sub-processors. The memory 145 is coupled to the CPU 143 and the memory 195 is non-transitory and may be one or more of readily available memory such as random access memory (RAM), read only memory (ROM), floppy disk drive, hard disk, or any other form of digital storage, local or remote. Support circuits 147 are coupled to the CPU 143 for supporting the processor in a conventional manner. Charged species generation, heating, and other processes are generally stored in the memory 145, typically as software routine. The software routine may also be stored and/or executed by a second CPU (not shown) that is remotely located from the processing chamber 100 being controlled by the CPU 143.

The memory 145 is in the form of computer-readable storage media that contains instructions, that when executed by the CPU 143, facilitates the operation of the chamber 100. The instructions in the memory 145 are in the form of a program product such as a program that implements the method of the present disclosure. The program code may conform to any one of a number of different programming languages. In one example, the disclosure may be implemented as a program product stored on a computer-readable storage media for use with a computer system. The program(s) of the program product define functions of the implementations (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips, or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are implementations of the present disclosure.

While the foregoing is directed to specific implementations, other and further embodiments may be devised without departing from the basic scope thereof, and the scope thereof is determined by the claims that follow.

1. A plasma processing system, comprising:
a processing chamber having chamber body defining a processing region and a plasma field;
a chamber seasoning system, the chamber seasoning system coupled to the processing chamber, the chamber seasoning system configured to season the processing region and the plasma field; and
a remote plasma cleaning system, the remote plasma cleaning system in communication with the processing chamber, the remote plasma cleaning system configured to clean the processing region and the plasma field.

2. The plasma process system of claim 1, wherein the processing chamber comprises:
a faceplate and an ion blocker plate, faceplate and the ion blocker plate defining the plasma field therebetween, wherein the face plate and the ion blocker plate are configured to connect to an RF power supply.

3. The plasma processing system of claim 2, wherein the processing chamber further comprises:
a spacer electronically isolating the faceplate from the ion blocker plate.

4. The plasma processing system of claim 2, wherein the ion blocker plate comprises:
a disc shaped body having a plurality of apertures formed therein, the plurality of apertures arranged in a hex pattern.

5. The plasma processing system of claim 4, further comprising:
a dual channel showerhead positioned beneath the ion blocker plate, the dual channel showerhead comprising a plurality of openings formed therethrough, the plurality of openings of the showerhead arranged in a pattern that is offset from the hex pattern of the ion blocker plate.

6. The plasma processing system of claim 5, wherein the dual channel showerhead further comprises:
one or more gas passages formed in the dual channel showerhead; and
a second plurality of openings formed in the dual channel showerhead, each of the second plurality of openings fluidly coupled to the one or more gas passages.

7. The plasma processing system of claim 1, wherein the chamber seasoning system comprises:
a first valve coupled to an upper manifold of the chamber body, the first valve configurable between an open position and a closed position; and
a second valve in fluid communication with the processing region.

8. The plasma processing system of claim 1, wherein the remote plasma cleaning system comprises:
a remote plasma generator; and
an upper split manifold coupled to the remote plasma generator, the upper split manifold comprising:
a first valve coupling the upper split manifold to an upper manifold of the processing chamber, the first valve configurable between an open state and a closed state.

9. The plasma processing system of claim 1, further comprising:
a second processing chamber having a chamber body defining a second processing region and a second plasma field, wherein the chamber seasoning system is coupled to the second processing chamber, the chamber seasoning system configured to season the second processing region and the second plasma field, and wherein the remote plasma cleaning system is in communication with the second processing chamber, the remote plasma cleaning system configured to clean the second processing region and the second plasma field.

10. A method of seasoning a processing chamber, comprising:
seasoning a first region of the processing chamber, comprising:
generating a plasma within the processing chamber; and
seasoning a second region of the processing chamber, wherein seasoning a second region of the processing chamber is performed subsequent to seasoning the first region.

11. The method of claim 10, wherein seasoning the first region of the processing chamber comprises:
opening a first valve between a chamber seasoning system and the processing chamber, wherein the first valve controls flow of a seasoning gas from the chamber seasoning system to the first region of the processing chamber.

12. The method of claim 11, wherein seasoning the first region of the processing chamber comprises:
preventing flow through closing a second valve between the chamber seasoning system and the processing chamber, wherein the second valve controls flow of the seasoning gas from the chamber seasoning system to the second region of the processing chamber.

13. The method of claim 10, wherein seasoning a second region of the processing chamber is performed subsequent to seasoning the first region, comprises:
opening a second valve between a chamber seasoning system and the processing chamber, wherein the second valve controls flow of the seasoning gas from the chamber seasoning system to the second region of the processing chamber.

14. The method of claim 10, wherein seasoning a second region of the processing chamber is performed subsequent to seasoning the first region, comprises:
preventing flow through closing a first valve between the chamber seasoning system and the processing chamber, wherein the first valve controls flow of the seasoning gas from the chamber seasoning system to the first region of the processing chamber.

15. The method of claim 10, wherein the first region of the processing chamber is a plasma field defined between a faceplate and a selective modulation device of the processing chamber.

16. The method of claim 15, wherein the second region of the processing chamber is a processing region defined between a showerhead and a pedestal of the processing chamber.

17. A method of processing a substrate, comprising:
generating a conductively coupled plasma within a plasma field defined between an ion blocker and a faceplate in a substrate processing chamber;
filtering ions in the conductively coupled plasmas while allowing radicals to pass through the ion blocker and into a processing region above the substrate; and
flowing a precursor gas through a showerhead into the processing region, such that the precursor gas and the radicals of the plasma react in the processing region.

18. The method of claim 17, wherein generating a conductively coupled plasma within a plasma field defined between an ion blocker and a faceplate in a substrate processing chamber, comprises:
applying RF power to the ion blocker and the faceplate to a reaction gas in the plasma region.

19. The method of claim 18, wherein the reaction gas is an oxygen based gas.

20. The method of claim 19, wherein the precursor gas is a silicon based gas.
